(19) United States
(12) Patent Application Publication
(10) Pub. No.: US 2020/0098571 A1
(43) Pub. Date: Mar. 26, 2020

(54) STORAGE DEVICE

(71) Applicant: TOSHIBA MEMORY CORPORATION, Tokyo (JP)

(72) Inventor: Kouji MATSUO, Ama Aichi (JP)

(73) Assignee: TOSHIBA MEMORY CORPORATION, Tokyo (JP)

(21) Appl. No.: 16/289,646

(22) Filed: Feb. 28, 2019

(30) Foreign Application Priority Data
Sep. 20, 2018 (JP) 2018-176087

(51) Int. Cl. H01L 21/28; H01L 21/822; H01L 27/06; H01L 27/11582; H01L 27/11524; H01L 27/11556; H01L 27/1157; H01L 29/423

(52) U.S. Cl. CPC H01L 21/28185; H01L 21/8221; H01L 27/0688; H01L 29/42332; H01L 27/11524; H01L 27/11556; H01L 27/1157; H01L 27/11582

(57) ABSTRACT

A storage device includes a crystalline silicon substrate, a stacked film including a plurality of crystalline silicon films provided on the crystalline silicon substrate and extending parallel to a crystalline silicon substrate surface and a plurality of insulating films extending parallel to the crystalline silicon substrate surface between the respective crystalline silicon films, a plurality of first conductive layers each having a disconnected end portion penetrating at least a portion of the stacked film and located below the stacked film, memory cells provided respectively between the plurality of crystalline silicon films and the plurality of first conductive layers, and a plurality of second conductive layers electrically connected to the plurality of crystalline silicon films respectively.

### CROSS-REFERENCE TO RELATED APPLICATIONS

This application is based upon and claims the benefit of priority from Japanese Patent Application No. 2018-176087, filed Sep. 20, 2018, the entire contents of which are incorporated herein by reference.

### FIELD

Embodiments described herein relate generally to a storage device.

### BACKGROUND

The development of a large-capacity nonvolatile memory has been actively carried out. This type of memory is capable of low voltage and low current operation, high speed switching, and miniaturization and high integration of memory cells.

In order to read and write data to and from a large-capacity nonvolatile memory, a memory cell and a peripheral circuit including a transistor are used in combination. When the memory cell is connected to the peripheral circuit by a wiring disposed under the memory cell, it is difficult to provide a low cost memory since the structure thereof is not simple.

Examples of related art include

### U.S. Pat. No. 8,633,535. DESCRIPTION OF THE DRAWINGS

FIG. 1 is a schematic cross-sectional view of a storage device according to a first embodiment.

FIG. 2 is a schematic cross-sectional view of a transistor according to the first embodiment.

FIG. 3 is a schematic cross-sectional view of the vicinity of a memory hole according to the first embodiment.

FIG. 4 is a schematic view illustrating a cross section of the storage device in the middle of a method of manufacturing a major portion of the storage device according to the first embodiment.

FIG. 5 is a schematic view illustrating a cross section of the storage device in the middle of the method of manufacturing the major portion of the storage device according to the first embodiment.

FIG. 6 is a schematic view illustrating a cross section of the storage device in the middle of the method of manufacturing the major portion of the storage device according to the first embodiment.

FIG. 7 is a schematic view illustrating a cross section of the storage device in the middle of the method of manufacturing the major portion of the storage device according to the first embodiment.

FIG. 8 is a schematic view illustrating a cross section of the storage device in the middle of the method of manufacturing the major portion of the storage device according to the first embodiment.

FIG. 9 is a schematic view illustrating a cross section of the storage device in the middle of the method of manufacturing the major portion of the storage device according to the first embodiment.

FIG. 10 is an equivalent circuit diagram of a portion of a storage device according to a second embodiment.

FIG. 11 is a schematic cross-sectional view of the storage device according to the second embodiment.

FIG. 12 is a schematic cross-sectional view of a portion of the storage device according to the second embodiment.

FIG. 13 is a schematic view illustrating a positional relationship between a control electrode, a control insulating film, and a control channel according to the second embodiment.

FIG. 14 is an equivalent circuit diagram of a control transistor and the periphery thereof according to the second embodiment.

### DETAILED DESCRIPTION

At least one embodiment provides a storage device having a small channel resistance.

In general, according to at least one embodiment, a storage device includes a crystalline silicon substrate, a stacked film including a plurality of crystalline silicon films provided on the crystalline silicon substrate and extending parallel to a crystalline silicon substrate surface and a plurality of insulating films extending parallel to the crystalline silicon substrate surface between the respective crystalline silicon films, a plurality of first conductive layers each having a disconnected end portion penetrating at least a portion of the stacked film and located below the stacked film, memory cells provided respectively between the plurality of crystalline silicon films and the plurality of first conductive layers, and a plurality of second conductive layers electrically connected to the plurality of crystalline silicon films respectively.

Hereinafter, embodiments will be described with reference to the drawings. In the drawings, the same or similar reference numerals will be given to the same or similar components.

### First Embodiment

A storage device of at least one embodiment includes a crystalline silicon substrate, a stacked film including a plurality of crystalline silicon films provided on the crystalline silicon substrate and extending parallel to a crystalline silicon substrate surface and a plurality of insulating films extending parallel to the crystalline silicon substrate surface between the respective crystalline silicon films, a plurality of first conductive layers each having a disconnected end portion penetrating at least a portion of the stacked film and located below the stacked film, memory cells provided respectively between the plurality of crystalline silicon films and the plurality of first conductive layers, and a plurality of second electrode pillars electrically connected to the plurality of crystalline silicon films respectively

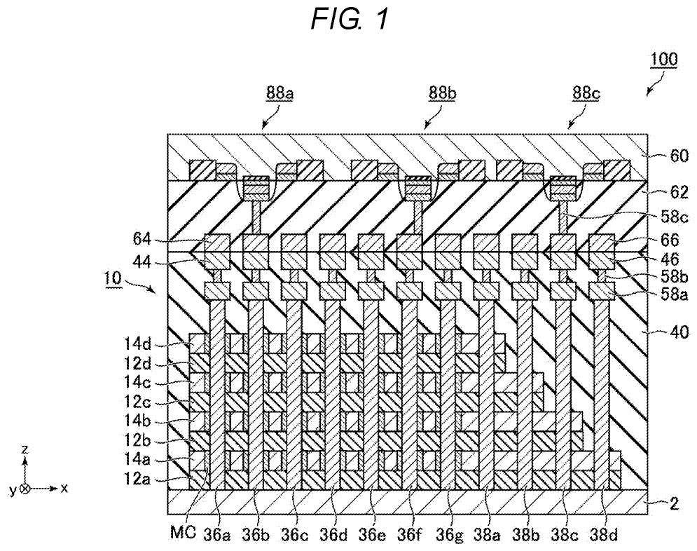

FIG. 1 is a schematic cross-sectional view of a storage device 100 of at least one embodiment.

In FIG. 1, the x direction is an example of a first direction, the y direction crossing perpendicularly to the x direction is an example of a second direction, and the z direction crossing perpendicularly to the x direction and the y direction is an example of a third direction.

The storage device 100 of at least one embodiment is a nonvolatile semiconductor memory.

A crystalline silicon substrate 2 is provided parallel to the xy plane.

An insulating layer 40 is provided on the crystalline silicon substrate 2. The insulating layer 40 preferably include silicon oxide, silicon oxynitride, or carbon added silicon oxide for bonding with a peripheral circuit insulator 62 to be described later.

A stack structure 10 is provided in the insulating layer 40. The stack structure 10 includes a plurality of crystalline silicon films 14 extending parallel to a crystalline silicon substrate surface and a plurality of insulating films 12 extending parallel to the crystalline silicon substrate surface between the respective crystalline silicon films 14. In FIG. 1, crystalline silicon films 14a, 14b, 14c and 14d as the plurality of crystalline silicon films 14 are illustrated. In addition, insulating films 12a, 12b, 12c and 12d as the plurality of insulating films 12 are illustrated. The plurality of insulating films 12 include, for example, silicon oxide or silicon nitride.

In addition, each of the number of crystalline silicon films 14 and the number of insulating films 12 illustrated in FIG. 1 is four, but the number thereof is not limited thereto.

The crystalline silicon film 14 functions as a word line WL of the storage device 100. The crystalline silicon film 14 located at a higher position has a smaller area.

A plurality of first conductive layers (conductive pillars) 36 penetrate the stack structure 10 so as to be parallel to the z direction. In FIG. 1, first conductive layers 36a, 36b, 36c, 36d, 36e, 36f and 36g as the plurality of first conductive layers 36 are illustrated. The plurality of first conductive layers 36 includes a conductor. The plurality of first conductive layers 36 include, for example, conductive polysilicon containing impurities, a metal, or metal silicide. End portions of the plurality of first conductive layers 36 located in the lower portion of the stack structure 10 are not connected to the other first conductive layers 36. In addition, the plurality of first conductive layers 36 may not penetrate all of the plurality of crystalline silicon films 14 and all of the plurality of insulating films 12, which penetrate the stack structure 10.

A plurality of memory cells MC are provided between the plurality of first conductive layers 36 and the plurality of crystalline silicon films 14. The plurality of memory cells MC are, for example, a plurality of field effect transistors (FETs).

In addition, in FIG. 1, seven first conductive layers 36 are provided, but the number thereof is not limited thereto.

By applying a voltage between the first conductive layer 36 and the crystalline silicon film 14, charges may be accumulated in the memory cell MC between the first conductive layer 36 and the crystalline silicon film 14 and information may be stored.

A plurality of second conductive layers (second conductive pillars) 38 are electrically connected to the respective crystalline silicon films 14 (functioning as channels of the storage device 100). Then, the plurality of second conductive layers 38 extend to the crystalline silicon substrate 2 so as to be parallel to the z direction. In FIG. 1, a plurality of second conductive layers 38a, 38b, 38c and 38d as the plurality of second conductive layers 38 are illustrated. The plurality of second conductive layers 38 include, for example, conductive polysilicon containing impurities, a metal, or metal silicide. For example, the second conductive layer 38 formed of a titanium (Ti) film, titanium nitride (TiN) film and tungsten (W) film be satisfactorily used. In addition, in FIG. 1, four second conductive layers 38 are provided, but the number thereof is not limited thereto.

A first electrode 44 is provided in the upper portion of the stack structure 10. The first electrode 44 includes copper (Cu). The first electrode 44 is electrically connected to one end of the plurality of first conductive layers 36 via a wiring 58a and a wiring 58b.

In addition, seven first electrodes 44 are illustrated in FIG. 1, but the number thereof is not limited thereto. In addition, a plurality of first conductive layers 36 may be electrically connected to one first electrode 44.

A second electrode 46 is provided in the upper portion of the stack structure 10. The second electrode 46 includes copper (Cu). The second electrode 46 is electrically connected to the plurality of second conductive layers 38 via the wiring 58a and the wiring 58b.

In addition, four second electrodes 46 are illustrated in FIG. 1, but the number thereof is not limited thereto. In addition, a plurality of second conductive layers 38 may be electrically connected to one second electrode 46.

A peripheral circuit substrate 60 is provided above the first electrode 44 and the second electrode 46. The peripheral circuit substrate 60 maybe formed of, for example, a silicon (Si) substrate or a germanium (Ge) substrate, which is a single-crystal semiconductor substrate, or a gallium arsenide (GaAs) substrate, a gallium nitride (GaN) substrate or a silicon carbide (SiC) substrate, which is a compound semiconductor substrate. The peripheral circuit substrate 60 is provided parallel to the xy plane.

The peripheral circuit insulator 62 is provided between the peripheral circuit substrate 60 and the insulating layer 40. The peripheral circuit insulator 62 preferably includes silicon oxide, silicon oxynitride, or carbon added silicon oxide for bonding with the insulating layer 40.

A third electrode 64 is provided in the peripheral circuit insulator 62 between the first electrode 44 and the peripheral circuit substrate 60. The third electrode 64 may include Cu. The third electrode 64 is electrically connected to a transistor 88 by, for example, a wiring 58c. In addition, the third electrode 64 is electrically connected to the first electrode 44.

In addition, seven third electrodes 64 are illustrated in FIG. 1, but the number thereof is not limited thereto. In addition, a plurality of first electrodes 44 may be electrically connected to one third electrode 64, or one first electrode 44 may be electrically connected to a plurality of third electrodes 64. In this way, the mode of connection is not particularly limited.

A fourth electrode 66 is provided in the peripheral circuit insulator 62 between the second electrode 46 and the peripheral circuit substrate 60. The fourth electrode 66 includes Cu. The fourth electrode 66 is electrically connected to the transistor 88 by, for example, the wiring 58c. In addition, the fourth electrode 66 is electrically connected to the second electrode 46.

In addition, four fourth electrodes 66 are illustrated in FIG. 1, but the number thereof is not limited thereto. In addition, a plurality of second electrodes 46 may be electrically connected to one fourth electrode 66, or one second electrode 46 may be electrically connected to a plurality of fourth electrodes 66. In this way, the mode of connection is not particularly limited.

The transistor 88 is provided in the peripheral circuit substrate 60. In FIG. 1, a transistor 88a, a transistor 88b, and a transistor 88 c are illustrated as the transistor 88. The transistor 88 is used for driving the memory cell MC. Three transistors 88 are illustrated in FIG. 1, but the number of transistors 88 is not particularly limited.

An example of an operation of the memory cell MC is described, for example, in Patent Document 1.

In addition, in FIG. 1, a description related to a barrier metal is omitted.

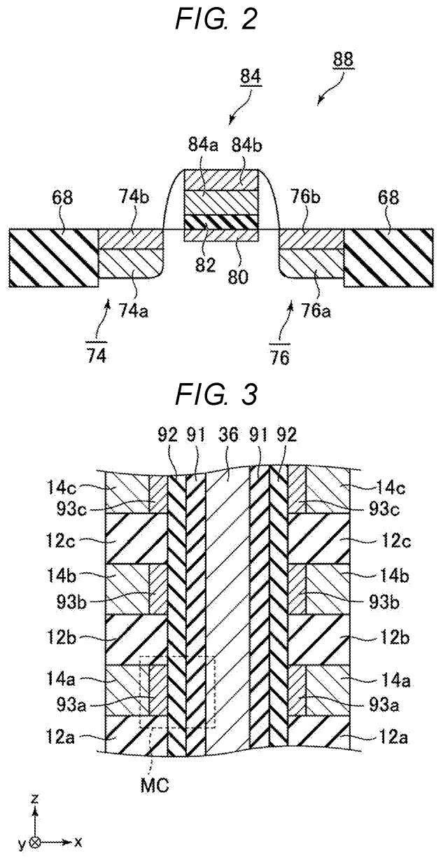

FIG. 2 is a schematic cross-sectional view of the transistor 88 according to the first embodiment. The transistor 88 includes an element isolation area 68, a source portion 74, a drain portion 76, a channel portion 80, a gate insulating film 82, and a gate portion 84.

The element isolation area 68 includes an insulator such as, for example, an oxide or a nitride.

The source portion 74 includes a source area 74a and a metal silicide portion 74b provided on the source area 74a and including metal silicide. The drain portion 76 includes a drain area 76a and a metal silicide portion 76b provided on the drain area 76a and including metal silicide.

The channel portion 80 includes, for example, a crystalline semiconductor.

The gate portion 84 includes a gate electrode 84a and a metal silicide portion 84b provided on the gate electrode 84a and including metal silicide.

The metal silicide is, for example, titanium silicide, aluminum silicide, nickel silicide, cobalt silicide, tantalum silicide, tungsten silicide, or hafnium silicide.

FIG. 3 is a schematic cross-sectional view of the vicinity of the first conductive layer 36 according to the first embodiment.

A tunnel insulating film 91 is provided around the first conductive layer 36. A charge storage film 92 is provided around the tunnel insulating film 91. A block insulating film 93 is provided around the charge storage film 92. In FIG. 3, block insulating films 93a, 93b, 93c and 93d are provided as the block insulating film 93.

The tunnel insulating film 91 is an insulation film, but is a film through which current flows when a predetermined voltage is applied thereto. The tunnel insulating film 91 includes, for example, silicon oxide. In addition, a silicon oxide layer, a silicon nitride layer, and a silicon oxide layer may be stacked in this order from the first conductive layer 36.

The charge storage film 92 is a film including a material capable of accumulating charges therein. The charge storage film 92 includes, for example, silicon nitride.

The block insulating film 93 is a film that prevents charges from flowing between the charge storage film 92 and the crystalline silicon film 14. The block insulating film 93 includes, for example, silicon oxide.

In FIG. 3, a region indicated by a dotted line is a single FET, and corresponds to the memory cell MC.

In FIG. 3, illustration of a barrier metal is omitted.

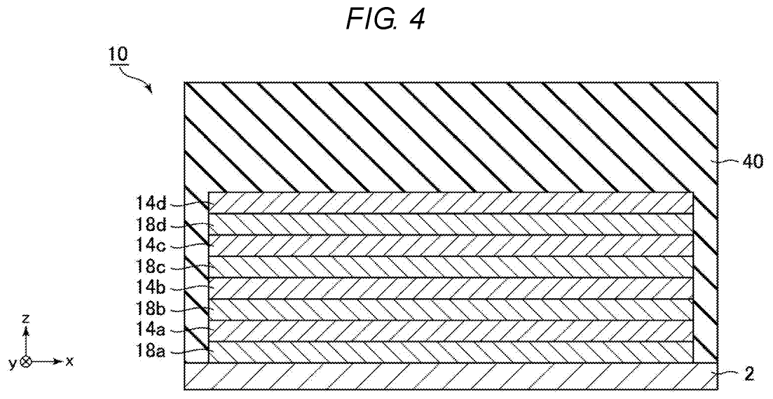

FIGS. 4 to 9 are schematic cross-sectional views illustrating the storage device in the middle of a method of manufacturing the storage device 100 according to the first embodiment.

First, a plurality of silicon germanium films 18 and the plurality of crystalline silicon films 14 are alternately formed on the crystalline silicon substrate 2, for example, by an epitaxial growth method. Specifically, a silicon germanium film 18a is formed on the crystalline silicon substrate 2, the crystalline silicon film 14a is formed on the silicon germanium film 18a, a silicon germanium film 18b is formed on the crystalline silicon film 14a, the crystalline silicon film 14b is formed on the silicon germanium film 18b, a silicon germanium film 18c is formed on the crystalline silicon film 14b, the crystalline silicon film 14c is formed on the silicon germanium film 18c, a silicon germanium film 18d is formed on the crystalline silicon film 14c, and the crystalline silicon film 14d is formed on the silicon germanium film 18d. Then, the insulating layer 40 is formed around the plurality of silicon germanium films 18 and the plurality of crystalline silicon films 14 (FIG. 4). Here, the silicon germanium film 18 is, for example, a silicon germanium film including at least 30 atom % of germanium.

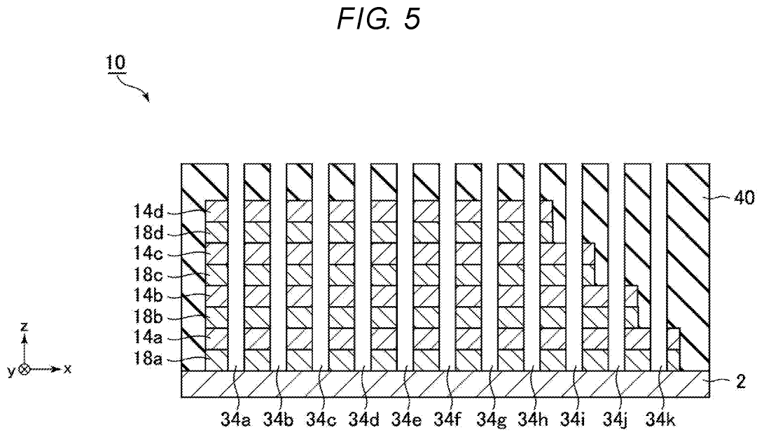

Next, for example, etching is performed in such a manner that the areas of the silicon germanium film 18b and the crystalline silicon film 14b are smaller than the areas of the silicon germanium film 18a and the crystalline silicon film 14a, that the areas of the silicon germanium film 18c and the crystalline silicon film 14c are smaller than the areas of the silicon germanium film 18b and the crystalline silicon film 14b, and that the areas of the silicon germanium film 18d and the crystalline silicon film 14d are smaller than the areas of the silicon germanium film 18c and the crystalline silicon film 14c. Next, through-holes 34 which penetrate the insulating layer 40, the plurality of silicon germanium films 18, and the plurality of crystalline silicon films 14 are formed by, for example, etching (FIG. 5). In FIG. 5, through-holes 34a, 34b, 34c, 34d, 34e, 34f, 34g, 34h, 34i, 34j and 34k are illustrated as the through-holes 34.

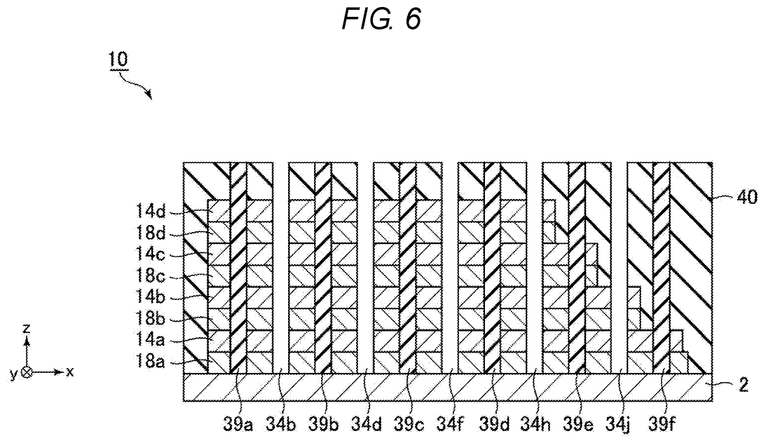

Next, a dummy film 39 is formed in some of the through-holes 34 (FIG. 6). Here, the dummy film 39 is, for example, an organic coating film. In FIG. 6, dummy films 39a, 39b, 39c, 39d, 39e and 39f are formed in the through-holes 34a, 34c, 34e, 34g, 34i and 34k, respectively.

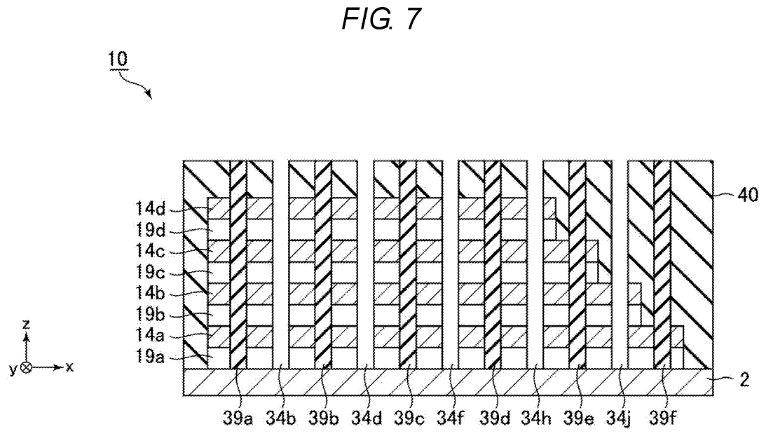

Next, the silicon germanium film 18 is removed by, for example, wet etching or dry etching using hydrogen chloride (HCl). Thus, empty holes 19a, 19b, 19c and 19d are formed in the portion from which the silicon germanium film 18 is removed (FIG. 7). At this time, the dummy film 39 serves as a reinforcing material for the crystalline silicon film 14 and the insulating layer 40. Therefore, even if the silicon germanium film 18 is removed, the shapes of the crystalline silicon film 14 and the insulating layer 40 are kept in the same manner as when the silicon germanium film 18 is formed.

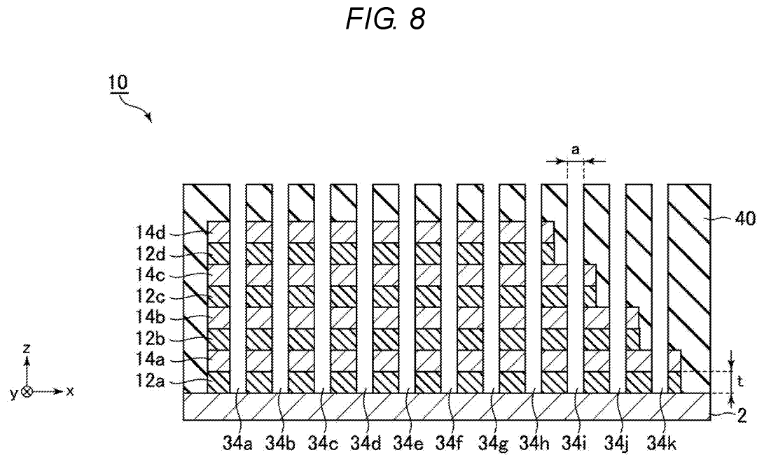

Next, the dummy film 39 is removed by, for example, ashing. Next, the insulating film 12 is formed in the empty hole 19. Next, a portion of the insulating film 12 formed in the through-hole 34 is removed (FIG. 8). At this time, when the diameter a of the through-hole 34 is greater than the film thickness t of the insulating film 12, the insulating film 12 may be formed so as to fill the empty hole 19, and the through-hole 34 may not be blocked by the insulating film 12 while the insulating film 12 is being formed.

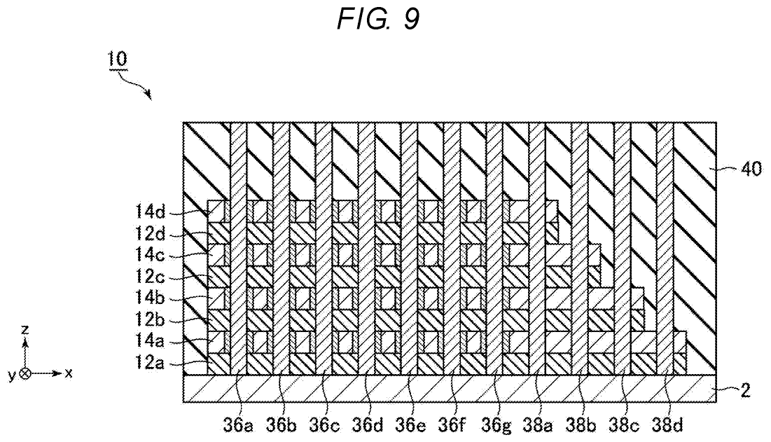

Next, for example, the crystalline silicon film 14 on the surfaces of the through-holes 34a, 34b, 34c, 34d, 34e, 34f and 34g is oxidized to form a block insulating film 93 (not illustrated). Next, although not illustrated, the charge storage film 92 and the tunnel insulating film 91 are sequentially formed in the through-holes 34a, 34b, 34c, 34d, 34e, 34f and 34g. Next, the first conductive layer 36 is formed in the through-holes 34a, 34b, 34c, 34d, 34e, 34f and 34g. In this way, the memory cell MC is formed between the first conductive layer 36 and the crystalline silicon film 14. Next, the second conductive layer 38 which is formed of, for example, a titanium (Ti) film, a titanium nitride (TiN) film, or a tungsten (W) film is formed in the through-holes 34h, 34i, 34j and 34k (FIG. 9). In addition, in FIG. 9, illustration of the Ti film and the TiN film is omitted.

Next, the wirings 58a and 58b connected to the first conductive layer 36 and the second conductive layer 38, the first electrode 44 including copper, and the second electrode 46 including copper are formed. Next, the third electrode 64 including copper, the fourth electrode 66 including copper, the transistor 88 electrically connected to the third electrode 64 or the fourth electrode 66 and formed in the peripheral circuit substrate 60, and the peripheral circuit insulator 62 provided around the third electrode 64 and the fourth electrode 66 are bonded so that the first electrode 44 is electrically connected to the third electrode 64 and the second electrode 46 is electrically connected to the fourth electrode 66 and so that the insulating layer 40 and the peripheral circuit insulator 62 are in direct contact with each other. Therefore, the storage device 100 of at least one embodiment is obtained.

Next, the action and effects of the storage device 100 of at least one embodiment will be described.

In the storage device 100 of at least one embodiment, the crystalline silicon film 14 is used as a channel layer. This makes it possible to obtain a storage device having improved mobility and a small channel resistance.

In the manufacture of the storage device 100, a stacked film of the crystalline silicon film 14 and the silicon germanium film 18 is formed, and thereafter the silicon germanium film 18 is removed. The lattice constants of the silicon germanium film 18 and the crystalline silicon film 14 are close to each other. Therefore, the crystalline silicon film 14 and the silicon germanium film 18 may be satisfactorily epitaxially grown alternately. Meanwhile, since the silicon germanium film 18 maybe easily removed by, for example, etching, the stacked structure 10 of the crystalline silicon film 14 and the insulating film 12 may be easily formed. Thus, it is possible to obtain a storage device having a small channel resistance.

According to the storage device 100 of the present embodiment, it is possible to obtain a storage device having a small channel resistance.

### Second Embodiment

A storage device of at least one embodiment includes a substrate having a circuit, a first cell substrate which is provided on the substrate and includes a plate-shaped first conductive layer extending parallel to a substrate surface so as to extend over a first area and a second area, a plate-shaped second conductive layer extending parallel to the first conductive layer so as to be spaced apart from the first conductive layer in the first area and to extend over the first area and the second area, a first contact connected to the circuit and connected to the first conductive layer in the first area, a second contact connected to the circuit and connected to the second conductive layer in the first area, a first wiring provided in the second area, a second wiring provided in the second area, a first channel penetrating the first conductive layer and the second conductive layer in the second area and connected to the first wiring, a second channel penetrating the first conductive layer and the second conductive layer in the second area and connected to the second wiring, a first memory cell provided between the first and second conductive layers and the first and second channels, a first control electrode provided above the first and second conductive layers, a first control channel provided in the first control electrode and connected to the first wiring, a second control channel provided in the first control electrode and connected to the second wiring, a first insulating film provided between the first and second control channels and the first control electrode, a first electrode provided on the first control electrode and connected to the first control channel, and a second electrode provided on the first control electrode and connected to the second control channel, and a second cell substrate which is provided on the first cell substrate and includes a plate-shaped third conductive layer extending parallel to the substrate surface so as to extend over the first area and the second area, a plate-shaped fourth conductive layer extending parallel to the third conductive layer so as to be spaced apart from the third conductive layer in the first area and to extend over the first area and the second area, a third contact connected to the circuit and connected to the third conductive layer in the first area, a fourth contact connected to the circuit and connected to the fourth conductive layer in the first area, a third wiring provided in the second area and connected to the first wiring, a fourth wiring provided in the second area and connected to the second wiring, a third channel penetrating the third conductive layer and the fourth conductive layer in the second area and connected to the third wiring, a fourth channel penetrating the third conductive layer and the fourth conductive layer in the second area and connected to the fourth wiring, a second memory cell provided between the third and fourth conductive layers and the third and fourth channels, a second control electrode provided above the third and fourth conductive layers, a third control channel provided in the second control electrode and connected to the third wiring, a fourth control channel provided in the second control electrode and connected to the fourth wiring, and a second insulating film provided between the third and fourth control channels and the second control electrode.

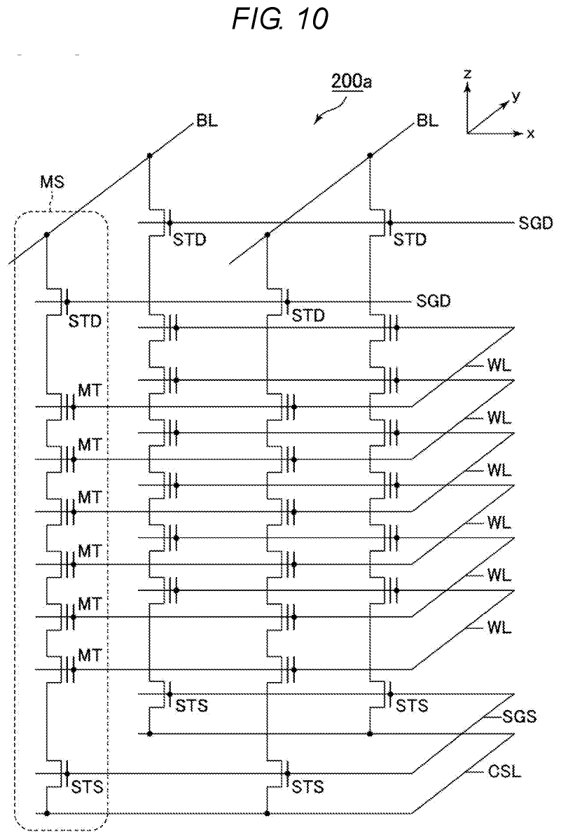

FIG. 10 is an equivalent circuit diagram of a portion (200a, 200b, or 200c) of a storage device 500 according to at least one embodiment. In the drawing, the x direction is an example of a first direction, the y direction crossing perpendicularly to the x direction is an example of a second direction, and the z direction crossing perpendicularly to the x direction and y direction is an example of a third direction.

The storage device 200a is a three-dimensional NAND flash memory in which memory cells are three-dimensionally arranged.

The storage device 200a includes a plurality of word lines WL, a common source line CSL, a source select gate line SGS, a plurality of drain select gate lines SGD, a plurality of bit lines BL, and a plurality of memory strings MS.

The memory string MS includes a source select transistor STS, a plurality of memory cell transistors MT, and a drain select transistor STD, which are connected in series between the common source line CSL and the bit line BL.

In addition, the number of word lines WL, the number of bit lines BL, the number of memory strings MS, and the number of drain select gate lines SGD are not limited to those in FIG. 10.

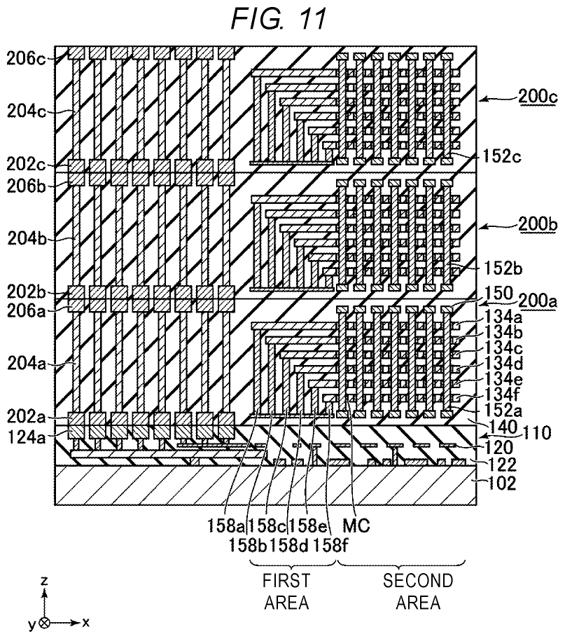

FIG. 11 is a schematic cross-sectional view of the storage device 500 according to the embodiment. The storage device 500 is a storage device formed by bonding the storage device 200a, the storage device 200b, and the storage device 200c on a substrate 102 having a circuit 110. The storage device 200a is an example of the first cell substrate and the storage device 200b is an example of the second cell substrate.

In FIG. 11, illustration of the source select gate line SGS, the drain select gate line SGD, the source select transistor STS, and the drain select transistor STD is omitted.

The substrate 102 is, for example, a semiconductor substrate. The substrate 102 is, for example, a silicon substrate. In FIG. 11, the substrate 102 is disposed so that the xy plane and the substrate plane are parallel to each other.

The circuit 110 is provided on the substrate 102. Therefore, the substrate 102 includes the circuit 110. For example, the circuit 110 is formed by forming a wiring 120 in an insulator 122 which includes, for example, silicon oxide. The circuit 110 is used to control the storage device 500.

An electrode 124a provided on the circuit 110 includes, for example, copper. An electrode 202a, a wiring 204a, and an electrode 206a provided in the storage device 200a include, for example, copper. An electrode 202b, a wiring 204b, and an electrode 206b provided in the storage device 200b include, for example, copper. An electrode 202c, a wiring 204c, and an electrode 206c provided in the storage device 200c include, for example, copper. When the storage device 500 is manufactured, bonding is performed in a state where the electrode 124a and the electrode 202a are in contact with each other, the electrode 206a and the electrode 202b are in contact with each other, and the electrode 206b and the electrode 202c are in contact with each other. Therefore, the input and output of signals from the circuit 110 to the electrode 206c are possible.

A first area and a second area are provided on the substrate 102. Then, a plurality of conductive layers 134 which extend parallel to the substrate surface of the substrate 102 extend over the first area and the second area. For example, the conductive layers 134a, 134b, 134c, 134d, 134e, and 134f are stacked with insulating layers 140 interposed therebetween. The conductive layer 134e is provided on the conductive layer 134f. The conductive layer 134d is provided on the conductive layer 134e. The conductive layer 134c is provided on the conductive layer 134d. The conductive layer 134b is provided on the conductive layer 134c. The conductive layer 134a is provided on the conductive layer 134b.

For example, the conductive layer 134a is provided in the first and second areas. The conductive layer 134b is provided in the first and second areas. In the x direction, the conductive layer 134b is shorter than the conductive layer 134a. The conductive layer 134b is spaced apart from the conductive layer 134a in the z direction and extends parallel to the conductive layer 134a. The conductive layer 134c is provided in the first and second areas. In the x direction, the conductive layer 134c is shorter than the conductive layer 134b. The conductive layer 134c is spaced apart from the conductive layer 134b in the z direction and extends parallel to the conductive layer 134b. The conductive layer 134d is provided in the first and second areas. In the x direction, the conductive layer 134d is shorter than the conductive layer 134c. The conductive layer 134d is spaced apart from the conductive layer 134c in the z direction and extends parallel to the conductive layer 134c. The conductive layer 134e is provided in the first and second areas. In the x direction, the conductive layer 134e is shorter than the conductive layer 134d. The conductive layer 134e is spaced apart from the conductive layer 134d in the z direction and extends parallel to the conductive layer 134d. The conductive layer 134f is provided in the first and second areas. In the x direction, the conductive layer 134f is shorter than the conductive layer 134e. The conductive layer 134f is spaced apart from the conductive layer 134e in the z direction and extends parallel to the conductive layer 134e.

In the first area, an electrode member 158 is provided. In an example of FIG. 11, for example, electrode members 158a, 158b, 158c, 158d, 158e and 158f are provided. Each of the electrode members functions as a contact that interconnects the conductive layer 134 of a corresponding hierarchy and the wiring 120 on the substrate 102 side.

The electrode member 158a is connected to the conductive layer 134a at a position at which an end portion of the conductive layer 134a in the first area protrudes, and extends to the substrate 102 having the circuit 110 and is connected to the circuit 110 using a wiring (not illustrated). The electrode member 158b is connected to the conductive layer 134b at a position at which an end portion of the conductive layer 134b in the first area protrudes, and extends to the substrate 102 having the circuit 110 and is connected to the circuit 110 using a wiring (not illustrated). The electrode member 158c is connected to the conductive layer 134c at a position at which an end portion of the conductive layer 134c in the first area protrudes, and extends to the substrate 102 having the circuit 110 and is connected to the circuit 110 using a wiring (not illustrated). The electrode member 158d is connected to the conductive layer 134d at a position at which an end portion of the conductive layer 134d in the first area protrudes, and extends to the substrate 102 having the circuit 110 and is connected to the circuit 110 using a wiring (not illustrated). The electrode member 158e is connected to the conductive layer 134e at a position at which an end portion of the conductive layer 134e in the first area protrudes, and extends to the substrate 102 having the circuit 110 and is connected to the circuit 110 using a wiring (not illustrated). The electrode member 158f is connected to the conductive layer 134f at a position at which an end portion of the conductive layer 134f in the first area protrudes, and extends to the substrate 102 having the circuit 110 and is connected to the circuit 110 using a wiring (not illustrated).

The electrode member 158a of the storage device 200a is an example of the first contact. The electrode member 158b of the storage device 200a is an example of the second contact. The electrode member 158a of the storage device 200b is an example of the third contact. The electrode member 158b of the storage device 200b is an example of the fourth contact.

Bit lines 150 extend parallel to the surface of the substrate 102 in the second area. The bit lines 150 extend, for example, in the y direction. The bit lines 150 of the storage device 200a are an example of the first wiring and the second wiring. In addition, the bit lines 150 of the storage device 200b are an example of the third wiring and the fourth wiring. One of the bit lines 150 of the storage device 200a is connected to a corresponding one of the bit lines 150 of the storage device 200b via, for example, the circuit 110. For example, the first wiring is connected to the third wiring, and the second wiring is connected to the fourth wiring.

A semiconductor layer (channel) 152 penetrates the conductive layers 134a, 134b, 134c, 134d, 134e and 134f in the second area, and is connected at one end thereof to the bit lines 150. In FIG. 11, semiconductor layers (channel) 152a of the storage device 200a, semiconductor layers (channels) 152b of the storage device 200b, and semiconductor layers (channels) 152c of the storage device 200c are illustrated as the semiconductor layer (channel) 152. The semiconductor layers (channels) 152a of the storage device 200a are an example of the first channel and the second channel. The semiconductor layers (channels) 152b of the storage device 200b are an example of the third channel and the fourth channel.

The memory cell MC is provided between the conductive layer 134 and the semiconductor layer (channel) 152. The memory cell MC includes, for example, a film including a material capable of accumulating charges therein. The memory cell MC of the storage device 200a is an example of the first memory cell and the memory cell MC of the storage device 200b is an example of the second memory cell.

For example, the conductive layer 134, the memory cell MC, and the semiconductor layer (channel) 152 constitute one memory cell transistor MT. A plurality of MCs provided around one semiconductor layer (channel) 152 are disposed in one memory string MS.

For example, tungsten, titanium nitride, or copper may be suitably used as a material of the conductive layer 134. In addition, any other conductive material such as, a metal, a metal semiconductor compound, or a semiconductor may be used as the material of the conductive layer 134.

For example, tungsten, titanium nitride, or copper may be suitably used as a material of the electrode member 158. In addition, any other conductive material such as, a metal, a metal semiconductor compound, or a semiconductor may be used as the material of the electrode member 158.

In addition, in FIG. 11, illustration of a barrier metal is omitted.

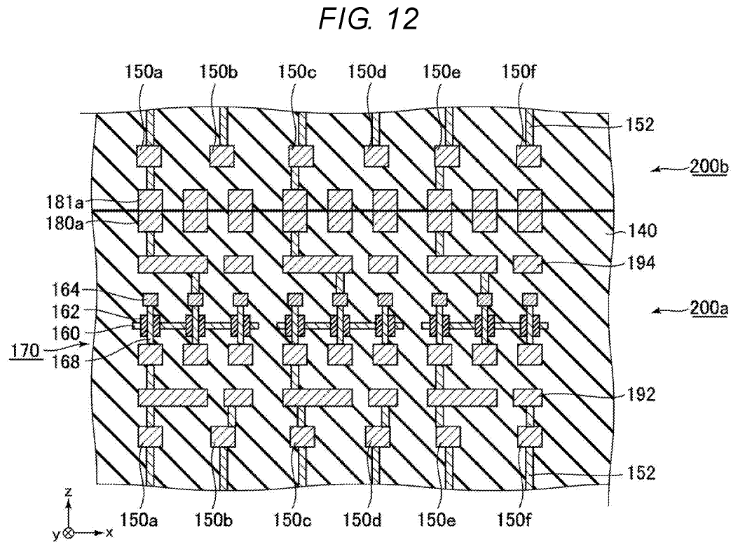

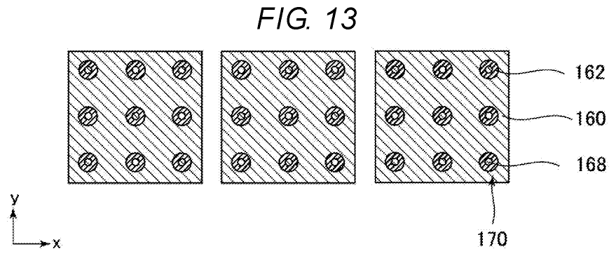

FIG. 12 is a schematic cross-sectional view of a portion of the storage device 500 according to the second embodiment.

A control transistor 170 includes a control electrode 160, a control channel 168 provided in the control electrode 160, and a control insulating film 162 provided between the control electrode 160 and the control channel 168. The control electrode 160 is provided above the bit line 150, and is formed of a conductive material such as, for example, a metal, a metal semiconductor compound, or a semiconductor. The control channel 168 is formed of, for example, a silicon material containing impurities. The control insulating film 162 is formed of, for example, silicon oxide. The control electrode 160 is a gate electrode of the control transistor 170. The control insulating film 162 is a gate insulating film of the control transistor 170.

For example, the control electrode 160 extends parallel to the surface of the substrate 102, and the control channel 168 penetrates the control electrode.

The bit line 150 is connected to the control channel 168 via a wiring 192. The control channel 168 is connected to an electrode 180a including copper, for example, via a wiring 164 and a wiring 194. The electrode 180a is connected to the bit line 150 of the storage device 200b via, for example, an electrode 181a of the storage device 200b. In this way, the bit line 150 of the storage device 200a and the bit line 150 of the storage device 200b are connected to each other. Similarly, the bit line 150 of the storage device 200b and the bit line of the storage device 200c are also connected to each other.

The control electrode 160 of the storage device 200a is an example of the first control electrode. The control channel 168 of the storage device 200a is an example of the first control channel and the second control channel. The control insulating film 162 of the storage device 200a is an example of the first insulating film. The electrode 180a of the storage device 200a is an example of the first electrode and the second electrode.

The control electrode 160 of the storage device 200b is an example of the second control electrode. The control channel 168 of the storage device 200b is an example of the third control channel and the fourth control channel. The control insulating film 162 of the storage device 200b is an example of the second insulating film.

FIG. 13 is a schematic view illustrating a positional relationship between the control electrode 160, the control insulating film 162, and the control channel 168 according to the second embodiment. In addition, in FIG. 13, illustration of other constituent requirements is omitted. In FIG. 13, it is illustrated that one control electrode 160 controls nine control transistors 170. In addition, the number of control transistors 170 controlled by one control electrode 160 is not limited thereto, but may be, for example, about 1000 (1024).

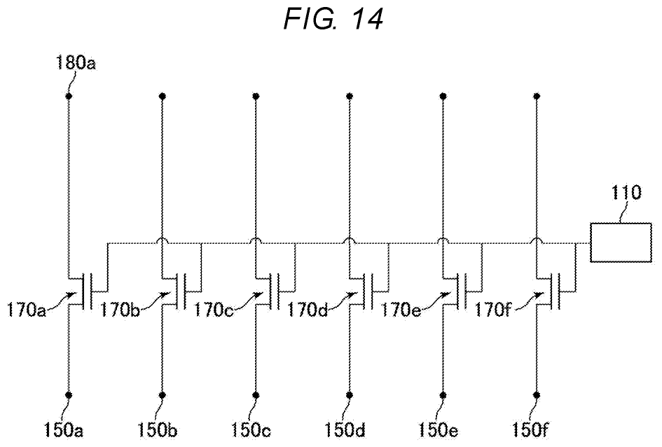

FIG. 14 is an equivalent circuit diagram of the control transistor 170 and the periphery thereof according to the second embodiment.

In FIG. 14, control transistors 170a, 170b, 170c, 170d, 170e and 170f as the control transistor 170 are illustrated. The gate electrodes of the control transistors 170a, 170b, 170c, 170d, 170e and 170f are connected to the circuit 110 using, for example, a wiring. It is possible to control the on/off of the control transistor 170 by controlling a voltage applied to the gate electrode using the circuit 110.

Next, the action and effects of the storage device 500 of the at least one embodiment will be described.

When a plurality of storage devices 200 formed in a plate shape are bonded to each other in a thickness direction, the storage device 500 may relatively easily achieve a high density. Here, when bonding the plurality of storage devices 200 to each other, for example, the word line WL is connected, for example, to a circuit provided on the substrate so that the word lines WL of the respective storage devices 200 formed in a plate shape are controlled independently of each other for storing and reading data. On the other hand, for example, the bit lines BL of the respective storage devices 200 are used as a common line and are connected to the circuit for storing and reading data.

When a defect such as short-circuit (short) occurs in one bit line BL of the plurality of storage devices 200, however, another bit line BL connected to the defective bit line BL is affected by the defect, which causes a considerable reduction in the yield of the memory cell MC.

Therefore, in the storage device 500 of at least one embodiment, the control transistors 170 connected to the respective bit lines BL are provided above the memory cell MC of the storage device 200. Through the use of the control transistors 170, when a defect occurs in the bit line BL, the control transistors 170 connected in series to, for example, about 1000 bit lines BL are turned off. Therefore, it is possible to prevent the influence of the defect on the other bit lines BL of the storage device 200 and to provide a storage device with a high yield.

The interval between the bit lines BL is, for example, about half pitch 20 nm. Therefore, when it is attempted to provide the control transistor 170 in a portion in which the bit line BL extends parallel to the surface of the substrate 102, since it is difficult to form the control transistor 170 or the wiring of the control transistor 170, a large space is required in the xy plane and it is difficult to miniaturize the storage device 500.

In the storage device 500 of at least one embodiment, the control transistor 170 is provided above the conductive layer 134. Since the space above the conductive layer 134 has a margin in comparison with the lateral side of the conductive layer 134 (a portion in which the bit line BL extends parallel to the surface of the substrate 102), it is possible to easily form the control transistor 170 without preventing miniaturization of the storage device 500.

The control transistor 170 may be easily formed when the control electrode 160 extends parallel to the surface of the substrate 102 and the control channel 168 is shaped so as to penetrate the control electrode.

According to the storage device of at least one embodiment, it is possible to provide a storage device with a high yield.

In addition, although certain embodiments describe a three-dimensional NAND flash memory, the present disclosure may also be applied to any other variable resistance type memory in which memory cells are three-dimensionally arranged.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein maybe made without departing from the spirit of the inventions. The accompanying claims and their equivalents are intended to cover such forms or modifications as would fall within the scope and spirit of the inventions.

What is claimed is:

1. A storage device comprising:
a crystalline silicon substrate;
a stacked film, including a plurality of crystalline silicon films provided on the crystalline silicon substrate and extending parallel to a crystalline silicon substrate surface, and a plurality of insulating films extending parallel to the crystalline silicon substrate surface between the respective crystalline silicon films;
a plurality of first conductive layers each having a disconnected end portion penetrating at least a portion of the stacked film, the disconnected end portion located below the stacked film;
memory cells provided respectively between the plurality of crystalline silicon films and the plurality of first conductive layers; and
a plurality of second conductive layers electrically connected to the plurality of crystalline silicon films respectively.

2. The storage device according to claim 1, wherein the plurality of first conductive layers are a plurality of gate electrodes.

3. The storage device according to claim 1, wherein one crystalline silicon film among the plurality of crystalline silicon films has an area smaller than an area of another crystalline silicon film among the plurality of crystalline silicon films provided below the one crystalline silicon film.

4. The storage device according to claim 3, wherein each crystalline silicon film among the plurality of crystalline silicon films has an area smaller than an area of any other crystalline silicon film among the plurality of crystalline silicon films provided below the each crystalline silicon film.

5. The storage device according to claim 2, wherein one crystalline silicon film among the plurality of crystalline silicon films has an area smaller than an area of another crystalline silicon film among the plurality of crystalline silicon films provided below the one crystalline silicon film.

6. The storage device according to claim 5, wherein each crystalline silicon film among the plurality of crystalline silicon films has an area smaller than an area of any other crystalline silicon film among the plurality of crystalline silicon films provided below the each crystalline silicon film.

7. The storage device according to claim 1, wherein the first and second conductive layers are shaped as conductive pillars.

8. The storage device according to claim 1, wherein the crystalline silicon films include word lines.

9. The storage device according to claim 1, wherein the memory cells include field effect transistors.

10. The storage device according to claim 1, further comprising a peripheral circuit disposed above, and electrically connected to, the first and second conductive layers.

11. The storage device according to claim 10, wherein the peripheral circuit includes a plurality of transistors configured to drive the memory cells.

12. The storage device according to claim 1, further comprising a plurality of charge storage films and a plurality of tunnel insulating films, respective of the tunnel insulating films arranged between respective of the first conductive layers and the charge storage films.

13. The storage device according to claim 12, further comprising a plurality of block insulating films, respective of the block insulating films arranged between respective of the charge storage films and memory cells.

14. A storage device comprising:
a substrate having a circuit;
a first cell substrate provided on the substrate and including:
a plate-shaped first conductive layer extending parallel to a substrate surface so as to extend over a first area and a second area;
a plate-shaped second conductive layer extending parallel to the first conductive layer so as to be spaced apart from the first conductive layer in the first area and to extend over the first area and the second area;
a first contact connected to the circuit and connected to the first conductive layer in the first area;
a second contact connected to the circuit and connected to the second conductive layer in the first area;
a first wiring provided in the second area;
a second wiring provided in the second area;
a first channel penetrating the first conductive layer and the second conductive layer in the second area and connected to the first wiring;
a second channel penetrating the first conductive layer and the second conductive layer in the second area and connected to the second wiring;
a first memory cell provided between the first and second conductive layers and the first and second channels;
a first control electrode provided above the first conductive layer and the second conductive layer;
a first control channel provided in the first control electrode and connected to the first wiring;
a second control channel provided in the first control electrode and connected to the second wiring;
a first insulating film provided between the first and second control channels and the first control electrode;
a first electrode provided on the first control electrode and connected to the first control channel; and
a second electrode provided on the first control electrode and connected to the second control channel; and
a second cell substrate provided on the first cell substrate and including:
a plate-shaped third conductive layer extending parallel to the substrate surface so as to extend over the first area and the second area;
a plate-shaped fourth conductive layer extending parallel to the third conductive layer so as to be spaced apart from the third conductive layer in the first area and to extend over the first area and the second area;
a third contact connected to the circuit and connected to the third conductive layer in the first area;
a fourth contact connected to the circuit and connected to the fourth conductive layer in the first area;
a third wiring provided in the second area and connected to the first wiring;
a fourth wiring provided in the second area and connected to the second wiring;
a third channel penetrating the third conductive layer and the fourth conductive layer in the second area and connected to the third wiring;
a fourth channel penetrating the third conductive layer and the fourth conductive layer in the second area and connected to the fourth wiring;
a second memory cell provided between the third and fourth conductive layers and the third and fourth channels;
a second control electrode provided above the third conductive layer and the fourth conductive layer;
a third control channel provided in the second control electrode and connected to the third wiring;
a fourth control channel provided in the second control electrode and connected to the fourth wiring; and
a second insulating film provided between the third and fourth control channels and the second control electrode.

15. The storage device according to claim 14, wherein the first control electrode and the second control electrode extend parallel to the substrate surface,
wherein the first control channel and the second control channel penetrate the first control electrode, and
the third control channel and the fourth control channel penetrate the second control electrode.
